(19) United States
(12) Patent Application Publication
(10) Pub. No.: US 2014/0150857 A1
(43) Pub. Date: Jun. 5, 2014

(54) MULTI-JUNCTION MULTI-TAB PHOTOVOLTAIC DEVICES

(71) Applicant: ZENA TECHNOLOGIES, INC., Cambridge, MA (US)

(72) Inventors: Young-June YU, Cranbury, NJ (US); Munib WOBER, Topsfield, MA (US)

(73) Assignee: ZENA TECHNOLOGIES, INC., Cambridge, MA (US)

(21) Appl. No.: 13/693,207

(22) Filed: Dec. 4, 2012

(51) Int. Cl. H01L 31/06; H01L 31/0725; H01L 31/18; H01L 31/076

(52) U.S. Cl. CPC H01L 31/06; H01L 31/076; H01L 31/0725; H01L 31/18
USPC 136/255; 438/71

(57) ABSTRACT

Described herein is a photovoltaic device operable to convert light to electricity, comprising a substrate, a first junction, a second junction and a third junction; wherein the first junction and the second junction are arranged with opposite polarity and the second junction and the third junction are arranged with opposite polarity. The photovoltaic device may further comprise a terminal directly electrically connected to anodes of the first and second junctions or to cathodes of the first and second junctions.

### CROSS-REFERENCE TO RELATED APPLICATIONS

This application is related to U.S. patent application Ser. Nos. 12/621,497, 12/633,297, 61/266,064, 12/982,269, 12/966,573, 12/967,880, 61/357,429, 12/974,499, 61/360,421, 12/910,664, 12/945,492, 12/966,514, 12/966,535, 13/047,392, 13/048,635, 13/106,851, 61/488,535, 13/288,131, 13/494,661, 13/543,307 and 61/563,279, the disclosures of which are hereby incorporated by reference in their entirety.

### BACKGROUND

A photovoltaic device, also called a solar cell is a solid state device that converts the energy of sunlight directly into electricity by the photovoltaic effect. Assemblies of cells are used to make solar modules, also known as solar panels. The energy generated from these solar modules, referred to as solar power, is an example of solar energy.

The photovoltaic effect is the creation of a voltage (or a corresponding electric current) in a material upon exposure to light. Though the photovoltaic effect is directly related to the photoelectric effect, the two processes are different and should be distinguished. In the photoelectric effect, electrons are ejected from a material's surface upon exposure to radiation of sufficient energy. The photovoltaic effect is different in that the generated electrons are transferred between different bands (i.e. from the valence to conduction bands) within the material, resulting in the buildup of a voltage between two electrodes.

Photovoltaics is a method for generating electric power by using solar cells to convert energy from the sun into electricity. The photovoltaic effect refers to photons of light-packets of solar energy-knocking electrons into a higher state of energy to create electricity. At higher state of energy, the electron is able to escape from its normal position associated with a single atom in the semiconductor to become part of the current in an electrical circuit. These photons contain different amounts of energy that correspond to the different wavelengths of the solar spectrum. When photons strike a PV cell, they may be reflected or absorbed, or they may pass right through. The absorbed photons can generate electricity. The term photovoltaic denotes the unbiased operating mode of a photodiode in which current through the device is entirely due to the light energy. Virtually all photovoltaic devices are some type of photodiode.

Since sunlight has a wide range energy spectrum, a single p-n junction device has a limitation in increasing the absorption beyond a certain level. To circumvent this limitation, approaches of stacking multiple p-n junctions with different semiconductor materials having different bandgaps, respectively, have been proposed. Such a multijunction photovoltaic device absorbs the sunlight more efficiently and produces more electricity than the single junction device does. In the multijunction photovoltaic device, incident sunlight should pass through a higher bandgap material and then through decreasingly lower bandgap materials toward the bottom of the device. This is because a short wavelength needs to be absorbed first by a high bandgap material located on the light-receiving side while the longer wavelength is transparent. The longer wavelength can be absorbed by underlying material which has smaller bandgap. Each junction in the multijunction photovoltaic device is electrically connected in series and should have identical photocurrent to avoid waste.

As illustrated in FIG. 1A, a series of active layers in a preferably monolithic semiconductor crystal is, starting from the top side where light enters: a window and antireflection layer 10 of high-conductivity p-type material, a semiconductive layer 12 containing an upper region 14 doped for p-type conductivity, a p-n junction 16 having a relatively high band-gap energy, and a lower region 18 of n-type, a high-conductivity transparent contact layer 20, a second semiconductive layer 22 containing an upper region 24 of n-type, an n-p junction 26 having a relatively low band-gap energy, and a lower p-type region 28. On the bottom of region 28 is bonded a metallic electrode 30 adapted to connect to an external lead 32.

Contact layers 10 and 20 may be of the same material as active layers 12 and 22, but more highly doped. Also, a high-conductivity p-type substrate layer may be present between lower active layer 28 and electrode 30.

Electrical contact to upper window 10 is made via a bonded metallic electrode 34, which is preferably a grid whose conductors cover only a small part of the surface area, leaving the rest transparent to incoming light. Grid 34 is adapted to connect to an external lead 36.

An intermediate lead 38 connects to contact layer 20 by an array of metallic grid conductors 40 deposited, as by evaporative deposition, in apertures 42, which are etched, as by photolithographic processes, through window layer 10 and upper semiconductor layer 12.

FIG. 1B shows an equivalent circuit of the device of FIG. 1A. The directions of current flow across the two junctions are opposing. The junctions cannot be connected directly in parallel because they generate different voltages.

### SUMMARY

Described herein is a photovoltaic device operable to convert light to electricity, comprising a substrate, a first junction, a second junction and a third junction; wherein the first junction and the second junction are arranged with opposite polarity (i.e., back-to-back) and the second junction and the third junction are arranged with opposite polarity (i.e., back-to-back).

According to an embodiment, at least one of the first, second and third junctions is textured.

According to an embodiment, the photovoltaic device further comprises a first terminal directly electrically connected to anodes of the first and second junctions or to cathodes of the first and second junctions.

According to an embodiment, the photovoltaic device further comprises a second terminal directly electrically connected to anodes of the second and third junctions or to cathodes of the second and third junctions.

According to an embodiment, the first, second and third junctions comprise epitaxial layers.

According to an embodiment, the photovoltaic device further comprises a second via configured to accommodate direct electrical connection to the second junction.

According to an embodiment, sidewall of the second via is covered by an electrically insulating material.

According to an embodiment, sidewall of the second via is covered by a material of the first junction.

According to an embodiment, the photovoltaic device further comprises a third via configured to accommodate direct electrical connection to the third junction.

According to an embodiment, sidewall of the second via is covered by an electrically insulating material.

According to an embodiment, the second and third junctions are configured such that electrical currents of the second and third junctions are essentially equal.

According to an embodiment, the photovoltaic device further comprises a fourth junction, wherein the third junction and the fourth junction are arranged with opposite polarity (i.e., back-to-back).

According to an embodiment, the photovoltaic device further comprises a third terminal directly electrically connected to anodes of the third and fourth junctions or to cathodes of the third and fourth junctions.

According to an embodiment, the fourth junction comprises epitaxial layers.

According to an embodiment, the fourth junction is texturized.

According to an embodiment, the photovoltaic device further comprises a fourth via configured to accommodate direct electrical connection to the fourth junction.

According to an embodiment, sidewall of the fourth via is covered by an electrically insulating material.

According to an embodiment, the fourth and third junctions are configured such that electrical currents of the fourth and third junctions are essentially equal.

According to an embodiment, bandgap of the third junction is smaller than bandgap of the fourth junction.

According to an embodiment, the first, second and third junctions comprise single crystalline material, micro-crystalline material, amorphous material, poly-crystalline material, and/or a combination thereof.

According to an embodiment, the fourth junction comprises single crystalline material, micro-crystalline material, amorphous material, poly-crystalline material, and/or a combination thereof.

According to an embodiment, the substrate is an electrically insulating material.

According to an embodiment, the substrate comprises glass, polymer or a combination thereof.

According to an embodiment, the substrate is flexible.

According to an embodiment, the substrate is transparent.

According to an embodiment, the photovoltaic device further comprises one or more structures essentially perpendicular to the substrate, wherein the first, second and third junctions are conformally disposed on the one or more structures.

According to an embodiment, at least some of the one or more structures each have a tapered portion and an untapered portion.

According to an embodiment, the tapered portion has a height of about 10% to 100% of a height of the structures.

According to an embodiment, the untapered portion is essentially uniform in width or diameter.

According to an embodiment, sidewall of the tapered portion and the substrate form an angle from 60 to 85 degrees.

According to an embodiment, the tapered portion is a cone or frustum.

According to an embodiment, the tapered portion does not have a planar surface at an apex thereof.

According to an embodiment, curvature (κ) of an apex of a planar cross-section through the tapered portion satisfies an equation

$$\geq \frac{n}{λ} ,$$

wherein n is the index or retraction of the taper portion and λ is 380 nm.

According to an embodiment, the first, second and third junctions are covered by a cladding layer.

According to an embodiment, a refractive index of the cladding layer is smaller than refractive indexes of the first, second and third junctions.

According to an embodiment, the one or more structures have the same composition as at least part of the substrate.

According to an embodiment, the first, second and third junctions are selected from a group consisting of a p-i-n junction, a p-n junction, and a heterojunction.

According to an embodiment, the first, second and third junctions comprise a heavily doped p type semiconductor material layer and a heavily doped n type semiconductor material layer, and optionally an intrinsic semiconductor layer sandwiched between the heavily doped p type semiconductor material layer and the heavily doped n type semiconductor material layer.

According to an embodiment, the first, second and third junctions comprise a semiconductor material selected from a group consisting of silicon, germanium, group III-V compound materials, group II-VI compound materials, and quaternary materials.

According to an embodiment, bandgap of the first junction is smaller than bandgap of the second junction; and wherein bandgap of the second junction is smaller than bandgap of the third junction.

According to an embodiment, the photovoltaic device further comprises at least one an electrically conductive layer disposed between a neighboring pair of the structures.

According to an embodiment, the photovoltaic device further comprises one or more transparent conductive oxide layers conformally disposed on the structures and the substrate.

According to an embodiment, thickness of a portion of the one or more transparent conductive oxide layers that is on the structures is smaller than thickness of another portion of the one or more transparent conductive oxide layers on the substrate.

According to an embodiment, a method of making a photovoltaic device with one or more structures wherein the one or more structures comprise a tapered portion; the method comprising: making the one or more structures by reactive ion etching the substrate with a metal layer as a mask; forming the tapered portion by etching the one or more structures.

According to an embodiment, the method further comprises: making a polymer mold by pouring precursors of the polymer onto the substrate following by curing; removing the polymer mold and coating the polymer mold with a layer of oxide; stamping an uncured ceramic material with the polymer mold; forming a ceramic structure by curing the uncured ceramic material.

According to an embodiment, a method of converting light to electricity comprising: exposing the photovoltaic device described herein to light; drawing an electrical current from the photovoltaic device.

According to an embodiment, a photo detector comprises the photovoltaic device described herein, wherein the photo detector is configured to output an electrical signal when exposed to light.

According to an embodiment, a method of detecting light comprises: exposing the photovoltaic device described herein to light; measuring an electrical signal from the photovoltaic device.

### BRIEF DESCRIPTION OF THE DRAWINGS

FIG. 1A is a schematic cross sectional view of a prior art photovoltaic device.

FIG. 1B shows an equivalent circuit of the device of FIG. 1A.

FIG. 2A shows a schematic cross-section of a photovoltaic device, according to an embodiment.

FIG. 2B shows an equivalent circuit of the device in FIG. 2A.

FIG. 3A shows a schematic cross-section of a photovoltaic device, according to an embodiment.

FIG. 3B shows an equivalent circuit of the device in FIG. 3A.

FIG. 4A shows a schematic cross-section of a photovoltaic device, according to an embodiment.

FIG. 4B shows an equivalent circuit of the device in FIG. 4A.

FIG. 5A shows a schematic cross-section of a photovoltaic device, according to an embodiment.

FIG. 5B shows an equivalent circuit of the device in FIG. 5A.

FIG. 6A and FIG. 6B each show a schematic cross-section of a photovoltaic device, according to an embodiment.

FIG. 6C shows an equivalent circuit of the device in FIGS. 6A-6B.

FIG. 7A and FIG. 7B each show a schematic cross-section of a photovoltaic device, according to an embodiment.

FIG. 7C shows an equivalent circuit of the device in FIGS. 7A-7B.

FIG. 8A shows a schematic cross-section of a photovoltaic device, according to an embodiment.

FIG. 8B shows an equivalent circuit of the device in FIG. 8A.

FIG. 9A shows a schematic cross-section of a photovoltaic device, according to an embodiment.

FIG. 9B shows an equivalent circuit of the device in FIG. 9A.

FIG. 10A and FIG. 10B each show a schematic cross-section of a photovoltaic device, according to an embodiment.

FIG. 10C shows an equivalent circuit of the device in FIGS. 10A-10B.

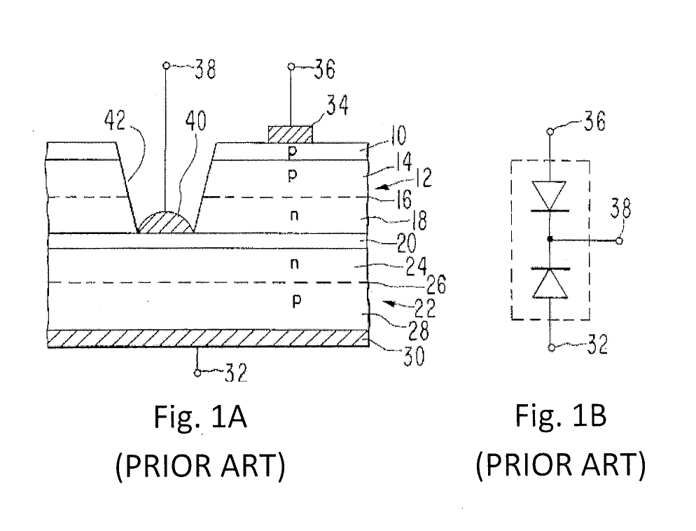

### DETAILED DESCRIPTION OF THE INVENTION

The term “photovoltaic device” as used herein means a device that can generate electrical power by converting light such as solar radiation into electricity. The term “single-crystal” as used herein means that the crystal lattice of the material is continuous and unbroken throughout the entire structures, with essentially no grain boundaries therein. An electrically conductive material can be a material with essentially zero band gap. The electrical conductivity of an electrically conductive material is generally above 10³ S/cm. A semiconductor can be a material with a finite band gap up to about 3 eV and general has an electrical conductivity in the range of 10³ to 10⁻⁸ S/cm. An electrically insulating material can be a material with a band gap greater than about 3 eV and generally has an electrical conductivity below 10⁻⁸ S/cm. The term “structures essentially perpendicular to the substrate” as used herein means that angles between the structures and the substrate are from 85° to 90°. The term “cladding layer” as used herein means a layer of substance surrounding the structures. The term “continuous” as used herein means having no gaps, holes, or breaks. The term “coupling layer” as used herein means a layer effective to guide light into the structures.

A group III-V compound material as used herein means a compound consisting of a group III element and a group V element. A group III element can be B, Al, Ga, In, Tl, Sc, Y, the lanthanide series of elements and the actinide series of elements. A group V element can be V, Nb, Ta, Db, N, P, As, Sb and Bi. A group II-VI compound material as used herein means a compound consisting of a group II element and a group VI element. A group II element can be Be, Mg, Ca, Sr, Ba and Ra. A group VI element can be Cr, Mo, W, Sg, O, S, Se, Te, and Po. A quaternary material is a compound consisting of four elements.

Described herein is a photovoltaic device operable to convert light to electricity, comprising a substrate, and at least two superposed junctions disposed on the substrate.

In an embodiment, the substrate comprises an electrically insulating material. The substrate can comprise glass, polymer, ceramic, one or more suitable electrically insulating materials, or a combination thereof.

In an embodiment, the substrate comprises an electrically conductive material.

In an embodiment, the substrate comprises a semiconductor such as silicon.

The substrate can comprise one or more suitable electrically conductive material, one or more suitable electrically insulating material, one or more semiconductor, or a combination thereof.

In an embodiment, the substrate is flexible. In an embodiment, the substrate is transparent.

In an embodiment, the substrate has a thickness of about 5 μm to about 300 μm, preferably of about 200 μm.

In an embodiment, a first junction is superposed on the substrate or is a part of the substrate, a second junction is superposed on the first junction, and a third junction, if present, is superposed on the second junction. The first, second and third junctions may be selected from a p-i-n junction, a p-n junction, and a heterojunction. More junctions (e.g., 4^{th} junction and 5^{th} junction) may be superposed on the second junction. In an embodiment, each of these junctions has a thickness of about 20 nm to about 200 nm, preferably about 100 nm. In an embodiment, each of these junctions has a thickness of about 0.5 μm to about 5 μm, preferably about 2 μm. The first, second and third junctions are arranged with opposite polarity, i.e., in each neighboring pair among the junctions, the spatial arrange is cathode-anode-anode-cathode or anode-cathode-cathode-anode. This arrangement is also called “back-to-back” arrangement.

In an embodiment, at least two of the at least two superposed junctions are conformally disposed on one or more structures essentially perpendicular to the substrate.

In an embodiment, the one or more structures essentially perpendicular to the substrate are cones, cylinders or prisms with a cross-section selected from a group consisting of elliptical, circular, rectangular, and polygonal cross-sections, strips. The one or more structures essentially perpendicular to the substrate may be a mesh. The term “mesh” as used herein means a web-like pattern or construction.

In an embodiment, the structures are cones, cylinders or prisms with a width from about 1 μm to about 10 μm, preferably about 2 μm.

In an embodiment, the structures are cones, cylinders or prisms with heights from about 2 μm to about 50 μm, preferably about 10 μm; a center-to-center distance between two closest structures of about 0:5 μm to about 20 μm, preferably about 4 μm.

In an embodiment, the structures are of the same composition as the substrate. In an embodiment, the structures are an electrically insulating material, such as glass, polymer, oxide, or a combination thereof.

In an embodiment, a top portion of the structures is tapered. The structures may be rounded or tapered by any suitable method such as isotropic etch. The tapered top portion can enhance light coupling to the structures.

In an embodiment, the tapered portion has a height from about 10% to 100% of the height of the structures, preferably about 33%. In an embodiment, portions of the structures except the tapered portion (i.e., untapered portions) are essentially uniform in width or diameter.

In an embodiment, sidewall of the tapered portion and the substrate form an angle from 60-85 degrees.

In an embodiment, the tapered portion is a cone in shape. In an embodiment, the tapered portion is a frustum. In an embodiment, the tapered portion does not have a planar surface at the apex thereof.

In an embodiment, curvature (κ) of the apex of a planar cross-section through the tapered portion satisfies the equation

$$\geq \frac{n}{λ} ,$$

wherein n is the index of refraction of the taper portion and λ is 380 nm.

The tapered portion may be made by a suitable method such as wet etch using a diluted silicon etchant.

In an embodiment, a photovoltaic device with one or more structures essentially perpendicular to the substrate wherein the one or more structures have a tapered portion can be made with a method comprising: making the one or more structures with a suitable method such as reactive ion etching a substrate with a circular or polygonal shaped metal layer as a mask; forming the tapered portion by etching the one or more structures with a suitable etchant such as a diluted silicon etchant; making a polymer (e.g., polydimethylsiloxane) mold by pouring precursors of the polymer onto the substrate following by curing; removing the polymer mold and coating the polymer mold with a layer of oxide such as Al₂O₃ by a suitable method such as atomic layer deposition; stamping an uncured ceramic material with the polymer mold; forming a ceramic structure by curing the uncured ceramic material. The ceramic structure may be used as the substrate for the photovoltaic device as disclosed herein.

In an embodiment, an electrically conductive layer may be disposed between the substrate or structures, and the first junction. In an embodiment, this electrically conductive layer is coextensive with the entire interface between the substrate or structures and the first junction. In an embodiment, this electrically conductive layer may have a thickness of about 0.1 μm to about 3 μm, preferably about 1 μm. In an embodiment, this electrically conductive layer may have a thickness of about 2 nm to about 100 nm, preferably about 10 nm. This electrically conductive layer may be transparent, semitransparent or opaque.

In an embodiment, a transparent electrically conductive layer may be disposed between any or all pairs of neighboring junctions. In an embodiment, the transparent electrically conductive layer is coextensive with the entire interface between a pair of neighboring junctions. This transparent electrically conductive layer may have a thickness of about 2 nm to about 100 nm, preferably about 10 nm.

This transparent electrically conductive layer preferably has a transmittance of at least 90% for visible light. This transparent electrically conductive layer preferably forms an Ohmic contact with the pair of neighboring junctions. In an embodiment, this transparent electrically conductive layer comprises any suitable material such as ITO (indium tin oxide), AZO (aluminum doped zinc oxide), ZIO (zinc indium oxide), ZTO (zinc tin oxide), etc. This transparent electrically conductive layer connects the pair of neighboring junctions in series. The transparent electrically conductive layer preferably is effective to prevent diffusion between the neighboring junctions.

In an embodiment, one of the junctions comprises a heavily doped (p+) semiconductor material layer, a lightly doped (n−) semiconductor material layer, and a heavily doped (n+) semiconductor material layer. The p+ layer, the n− layer and the n+ layer form a p-n junction or heterojunction. The p+ layer, the n− layer and the n+ layer may be different semiconductor materials or the same semiconductor materials. The p+ layer, the n− layer and the n+ layer may be single crystalline, polycrystalline or amorphous.

In an embodiment, one of the junctions comprises a heavily doped (p+) semiconductor material layer, a lightly doped (p−) semiconductor material layer, and a heavily doped (n+) semiconductor material layer. The p+ layer, the p− layer and the n+ layer form a p-n junction or heterojunction. The p+ layer, the p− layer and the n+ layer may be different semiconductor materials or the same semiconductor materials. The p+ layer, the p− layer and the n+ layer may be single crystalline, polycrystalline or amorphous.

In an embodiment, one of the junctions comprises a heavily doped p type (p+) semiconductor material layer, an intrinsic (i) semiconductor layer and a heavily doped n type (n+) semiconductor material layer. The p+ layer, i layer, and the n+ layer form a p-i-n junction. The p+ layer, i layer, and the n+ layer may be single crystalline, polycrystalline (interchangeably referred to as “multicrystalline”), microcrystalline (“μc”) (interchangeably referred to as “nanocrystalline” or “nc”) or amorphous. In an embodiment, the junctions comprise one or more semiconductor materials selected from a group consisting of silicon, germanium, group III-V compound materials, group II-VI compound materials, and quaternary materials.

Nanocrystalline semiconductor, also known as microcrystalline semiconductor, is a form of porous semiconductor. It is an allotropic form of semiconductor with paracrystalline structure—is similar to amorphous semiconductor, in that it has an amorphous phase. Nanocrystalline semiconductor differs from amorphous semiconductor in that nanocrystalline semiconductor has small crystalline grains within the amorphous phase. This is in contrast to polycrystalline semiconductor (e.g., poly-Si) which consists solely of crystalline grains, separated by grain boundaries.

In an embodiment, the band gap of an inner junction (i.e., a junction closer to the structures) is smaller than the band gap of an outer junction (i.e., a junction farther from the structures).

Tables 1 and 2 show exemplary materials and combinations of the junctions.

TABLE 1

| | | | | 4^{th} junction |
|---|---|---|---|---|
| | 1^{st} junction | | | (superposed |
| | (superposed | | | on the 3^{rd} |
| | on and | 2^{nd} junction | 3^{rd} junction | junction and |
| | closest to the | (superposed | (superposed | farthest from |
| | structures/ | on the 1^{st} | on the 2^{nd} | the structures/ |
| | substrate) | junction) | junction) | substrate) |
| Two | Poly-Si | Si n+/n/p+ | (none) | (none) |
| junctions | p+/p/n+ | or | | |
| on the | or | GaAs | | |
| structures/ | Si p+/p/n+ | n+/n/p/p+ | | |
| substrate | or | | | |
| | Ge p+/p/n+ | | | |
| | or | | | |
| | InGaAs | | | |
| | p+/p/n/n+ | | | |
| Three | Si p+/p/n+ | InGaAs | (Al)GaInP | (none) |
| junctions | or | n+/n/p/p+ | p+/p/n/n+ | |
| on the | Ge p+/p/n+ | or | | |
| structures/ | or | GaAs | | |
| substrate | InGaAs | n+/n/p/p+ | | |
| | p+/p/n/n+ | | | |
| Four | Ge p+/p/n+ | GaInNAs | Ga(In)As | (Al)GaInP |
| junctions | or | n+/n/p/p+ | p+/p/n/n+ | p+/p/n/n+ |
| on the | InGaAs | | | |
| structures/ | p+/p/n/n+ | | | |
| substrate | | | | |

TABLE 2

| | 1^{st} junction | | |
|---|---|---|---|
| | (superposed on | | |
| | and closest to | 2^{nd} junction | 3^{rd} junction |
| | the structures/ | (superposed on the 1^{st} | (superposed on the |
| | substrate) | junction) | 2^{nd junction)} |
| Two | Poly-Si | a-Si n+/i/p+ | (none) |
| junctions | p+/p/n+ | or | |
| on the | or | c-Si n+/n/p+ | |
| structures/ | c-Si p+/p/n+ | or | |
| substrate | or | CuGaSe n+/i/p+ | |
| | c-Ge p+/p/n+ | | |
| | or | | |
| | a-Si p+/i/n+ | | |
| | or | | |
| | nc-Si p+/p/n+ | | |
| | or | | |
| | a-SiGe p+/i/n+ | | |
| | or | | |
| | CuInSe p+/i/n+ | | |
| Three | c-Si p+/p/n+ | a-SiGe n+/i/p+ | a-Si p+/i/n+ |
| junctions | or | or | or |
| on the | c-Ge p+/p/n+ | nc-Si n+/i/p+ | a-SiC p+/i/n+ |
| structures/ | or | | |
| substrate | a-Si p+/i/n+ | | |
| | or | | |
| | nc-Si p+/p/n+ | | |
| | or | | |
| | a-SiGe p+/i/n+ | | |

In an embodiment, a cladding layer may be disposed conformally on the outermost junction (i.e., the junction that is among those junctions superposed on the structures/substrate and is not between another junction and the structures). A transparent electrically conductive layer may be disposed between the outermost junction and the cladding layer.

The cladding layer is substantially transparent to visible light with a transmittance of at least 50%. The cladding layer may be made of an electrically conductive material or an electrically insulating material. In an embodiment, the cladding layer is a transparent conductive oxide. In an embodiment, the cladding layer is a material selected from a group consisting of indium tin oxide, aluminum doped zinc oxide, zinc indium oxide, and zinc tin oxide. In an embodiment, the cladding layer is a material selected from a group consisting of Si₃N₄, Al₂O₃, SiO₂, and HfO₂. In an embodiment, the cladding layer has a refractive index of about 2. In an embodiment, the cladding layer has a refractive index of about 1.5. In an embodiment, the cladding layer has a refractive index lower than that of any junctions between the cladding layer and the structures. In an embodiment, the cladding layer has a thickness from about 10 nm to about 500 nm, preferably about 200 nm. In an embodiment, the cladding layer is configured as an electrode of the photovoltaic device.

According to an embodiment, a conductive (e.g., metallic) layer is disposed between the structures and the conductive layer is above the junctions. The conductive layer may be a material selected from a group consisting of ZnO, Ni, Pt, Al, Au, Ag, Pd, Cr, Cu, Ti, and a combination thereof. The conductive layer is preferably an electrically conductive material such as a metal. The conductive layer preferably has a reflectance (i.e., the fraction of incident electromagnetic power that is reflected) of at least 50% for visible light (i.e., light have a wavelength from 390 to 750 nm) of any wavelength. The conductive layer may have a thickness of at least 5 nm, preferably from about 20 nm to about 200 nm (e.g., about 80 nm). The conductive layer between the structures is preferably connected. The conductive layer may be functional to reflect light incident thereon to the structures so that the light is absorbed by the structures; and/or the conductive layer is functional as an electrode of the photovoltaic device. The term “electrode” as used herein means a conductor used to establish electrical contact with the photovoltaic device.

In an embodiment, space between the structures may be filled with a filler material such as a polymer. The filler material preferably is transparent and/or has a low refractive index. In an embodiment, a top surface of the filler material comprises one or more microlenses configured to concentrate incident light on the photovoltaic device onto the structures.

In an embodiment, a method of making the photovoltaic device comprises: generating a pattern of openings in a resist layer using a lithography technique, wherein locations and shapes of the openings correspond to location and shapes of the structures; forming the structures and regions therebetween by etching the substrate; depositing the reflective layer to the bottom wall. A resist layer as used herein means a thin layer used to transfer a pattern to the substrate, which the resist layer is deposited upon. A resist layer can be patterned via lithography to form a (sub)micrometer-scale, temporary mask that protects selected areas of the underlying substrate during subsequent processing steps. The resist is generally proprietary mixtures of a polymer or its precursor and other small molecules (e.g. photoacid generators) that have been specially formulated for a given lithography technology. Resists used during photolithography are called photoresists. Resists used during e-beam lithography are called e-beam resists. A lithography technique can be photolithography, e-beam lithography, holographic lithography. Photolithography is a process used in microfabrication to selectively remove parts of a thin film or the bulk of a substrate. It uses light to transfer a geometric pattern from a photo mask to a light-sensitive chemical photo resist, or simply “resist,” on the substrate. A series of chemical treatments then engraves the exposure pattern into the material underneath the photo resist. In complex integrated circuits, for example a modern CMOS, a wafer will go through the photolithographic cycle up to 50 times. E-beam lithography is the practice of scanning a beam of electrons in a patterned fashion across a surface covered with a film (called the resist), (“exposing” the resist) and of selectively removing either exposed or non-exposed regions of the resist (“developing”). The purpose, as with photolithography, is to create very small structures in the resist that can subsequently be transferred to the substrate material, often by etching. It was developed for manufacturing integrated circuits, and is also used for creating nanotechnology artifacts.

In an embodiment, the structures and regions therebetween are formed by deep etch followed by isotropic etch. A deep etch is a highly anisotropic etch process used to create deep, steep-sided holes and trenches in wafers, with aspect ratios of often 20:1 or more. An exemplary deep etch is the Bosch process. The Bosch process, also known as pulsed or time-multiplexed etching, alternates repeatedly between two modes to achieve nearly vertical structures: 1. a standard, nearly isotropic plasma etch, wherein the plasma contains some ions, which attack the wafer from a nearly vertical direction (For silicon, this often uses sulfur hexafluoride (SF₆)); 2. deposition of a chemically inert passivation layer (for instance, C₄F₈ source gas yields a substance similar to Teflon). Each phase lasts for several seconds. The passivation layer protects the entire substrate from further chemical attack and prevents further etching. However, during the etching phase, the directional ions that bombard the substrate attack the passivation layer at the bottom of the trench (but not along the sides). They collide with it and sputter it off, exposing the substrate to the chemical etchant. These etch/deposit steps are repeated many times over resulting in a large number of very small isotropic etch steps taking place only at the bottom of the etched pits. To etch through a 0.5 mm silicon wafer, for example, 100-1000 etch/deposit steps are needed. The two-phase process causes the sidewalls to undulate with an amplitude of about 100-500 nm. The cycle time can be adjusted: short cycles yield smoother walls, and long cycles yield a higher etch rate. Isotropic etch is non-directional removal of material from a substrate via a chemical process using an etchant substance. The etchant may be a corrosive liquid or a chemically active ionized gas, known as a plasma.

In an embodiment, a method of converting light to electricity comprises: exposing the photovoltaic device to light; drawing an electrical current from the photovoltaic device. The electrical current can be drawn from the wavelength-selective layer.

In an embodiment, a photo detector comprises the photovoltaic device, wherein the photo detector is configured to output an electrical signal when exposed to light.

In an embodiment, a method of detecting light comprises exposing the photovoltaic device to light; measuring an electrical signal from the photovoltaic device. The electrical signal can be an electrical current, an electrical voltage, an electrical conductance and/or an electrical resistance. A bias voltage is applied to the structures in the photovoltaic device.

In an embodiment, photovoltaic devices produce direct current electricity from sun light, which can be used to power equipment or to recharge a battery, A practical application of photovoltaics was to power orbiting satellites and other spacecraft, but today the majority of photovoltaic modules are used for grid connected power generation. In this case an inverter is required to convert the DC to AC. There is a smaller market for off-grid power for remote dwellings, boats, recreational vehicles, electric cars, roadside emergency telephones, remote sensing, and cathodic protection of pipelines. In most photovoltaic applications the radiation is sunlight and for this reason the devices are known as solar cells. In the case of a p-n junction solar cell, illumination of the material results in the creation of an electric current as excited electrons and the remaining holes are forced to move in different directions by the built-in electric field of the depletion region and by diffusion. Solar cells are often electrically connected and encapsulated as a module. Photovoltaic modules often have a sheet of glass on the front (sun up) side, allowing light to pass while protecting the semiconductor wafers from the elements (rain, hail, etc.). Solar cells are also usually connected in series in modules, creating an additive voltage. Connecting cells in parallel will yield a higher current. Modules are then interconnected, in series or parallel, or both, to create an array with the desired peak DC voltage and current.

In an embodiment, the photovoltaic device can also be associated with buildings: either integrated into them, mounted on them or mounted nearby on the ground. The photovoltaic device can be retrofitted into existing buildings, usually mounted on top of the existing roof structure or on the existing walls. Alternatively, the photovoltaic device can be located separately from the building but connected by cable to supply power for the building. The photovoltaic device can be used as a principal or ancillary source of electrical power. The photovoltaic device can be incorporated into the roof or walls of a building.

In an embodiment, the photovoltaic device can also be used for space applications such as in satellites, spacecrafts, space stations, etc. The photovoltaic device can be used as main or auxiliary power sources for land vehicles, marine vehicles (boats) and trains. Other applications include road signs, surveillance cameras, parking meters, personal mobile electronics (e.g., cell phones, smart phones, laptop computers, personal media players).

### EXAMPLES

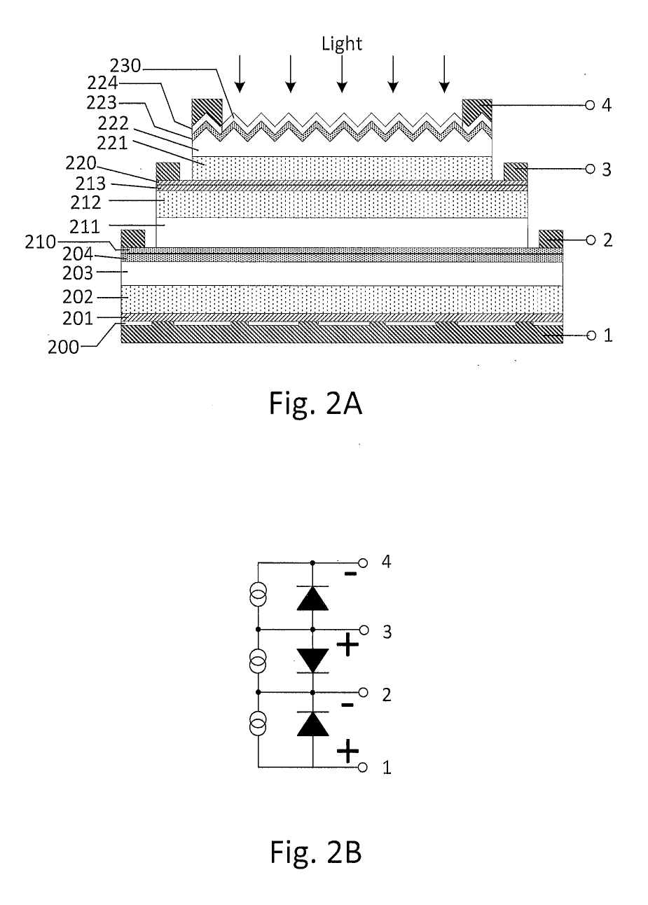

FIG. 2A shows a schematic cross-section of a photovoltaic device, according to an embodiment. FIG. 2B shows an equivalent circuit of the device in FIG. 2A. This device comprises the following layers:
200: a dielectric layer for passivation of layer 201 and insulation;
201: a p+ doped layer of a first junction;
202: a p doped layer of the first junction;
203: an n doped layer of the first junction;
204: a buffer layer in case that layer 210 is a III-V compound material. Otherwise, layer 204 is an n+ doped layer of the first junction;
210: an n+ doped layer of a second junction;
211: an n doped layer of the second junction;
212: a p doped layer of the second junction;
213: a p+ doped layer of the second junction;
220: a p+ doped layer of the third junction;
221: a p doped layer of the third junction
222: a n doped layer of the third junction;
223: an n+ doped layer of the third junction;
224: an n+ contact layer;
230: a dielectric layer for passivation of layer 222 and antireflection.

In this embodiment, the first, second and third junctions are depicted planar but can have non-planar shapes. Bandgap of the first junction is smaller than bandgap of the second junction, which is smaller than bandgap of the third junction. Layer 222 is texturized for enhancing light absorption. Terminals 1-4 in FIGS. 2A-2B are metal electrodes. Materials of the first, second, and third junctions may be selected from Table 1. Layers 201-204, 210-213, and 220-224 are preferably epitaxial layers.

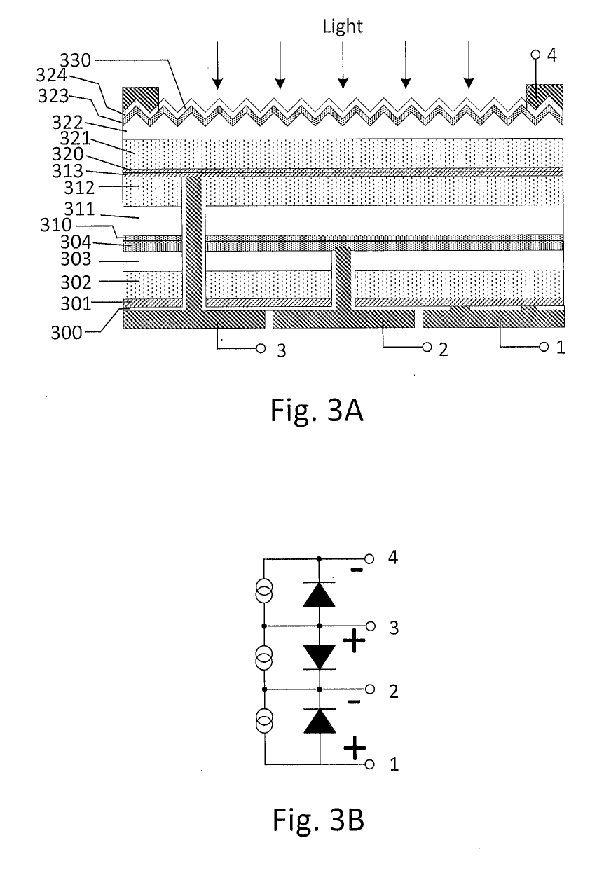

FIG. 3A shows a schematic cross-section of a photovoltaic device, according to an embodiment. FIG. 3B shows an equivalent circuit of the device in FIG. 3A. This device comprises the following layers:
300: a dielectric layer for passivation and insulation of layers 301-304 and 310-312;
301: a p+ doped layer of a first junction;
302: a p doped layer of the first junction;
303: an n doped layer of the first junction;
304: a buffer layer in case that layer 310 is a III-V compound material, otherwise, layer 304 is an n+ doped layer of the second junction;
310: an n+ doped layer of the second junction;
311: an n doped layer of the second junction;
312: a p doped layer of the second junction;
313: a p+ doped layer of the second junction;
320: a p+ doped layer of the third junction;
321: a p doped layer of the third junction;
322: a n doped layer of the third junction;
323: an n+ doped layer of the third junction;
324: a contact layer;
330: a dielectric layer for passivation and antireflection.

In this embodiment, the first, second and third junctions are depicted planar but can have non-planar shapes. Bandgap of the first junction is smaller than bandgap of the second junction, which is smaller than bandgap of the third junction. Layer 322 is texturized for enhancing light absorption. Terminals 1-4 in FIGS. 3A-3B are metal electrodes. Electrical connection to the third junction is made by a via through which terminal 3 passes. Similarly, electrical connection to the second junction is made by another via through which terminal 2 passes. Layer 300 extends throughout the sidewall of these vias to provide electrical insulation. The vias may be made by a suitable method such as laser or deep RIE (reactive ion etching). Materials of the first, second, and third junctions may be selected from Table 1. Layers 301-304, 310-313, and 320-324 are preferably epitaxial layers.

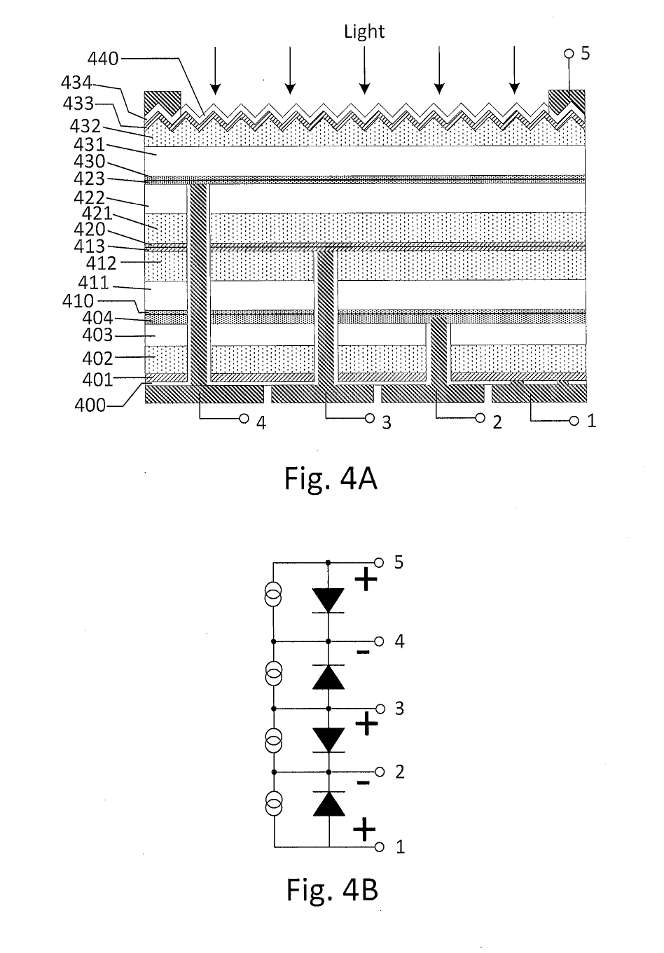

FIG. 4A shows a schematic cross-section of a photovoltaic device, according to an embodiment. FIG. 4B shows an equivalent circuit of the device in FIG. 4A. This device comprises the following layers:
400: a dielectric layer for passivation and insulation of layers 401-404, 410-413 and 420-422;
401: a p+ doped layer of a first junction;
402: a p doped layer of the first junction;
403: an n doped layer of the first junction;
404: a buffer layer in case that layer 410 is a III-V compound material; otherwise, layer 404 is an n+ doped layer of the first junction;
410: an n+ doped layer of the second junction;
411: an n doped layer of the second junction;
412: a p doped layer of the second junction;
413: a p+ doped layer of the second junction;
420: a p+ doped layer of the third junction;
421: a p doped layer of the third junction;
422: a n doped layer of the third junction;
423: an n+ doped layer of the third junction;
430: an n+ doped layer of the fourth junction;
431: an n doped layer of the fourth junction;
432: a p doped layer of the fourth junction;
433: a p+ doped layer of the fourth junction;
434: a contact layer;
440: a dielectric layer for passivation and antireflection.

In this embodiment, the first, second, third and fourth junctions are depicted planar but can have non-planar shapes. Bandgap of the first junction is smaller than bandgap of the second junction; bandgap of the second junction is smaller than bandgap of the third junction; and bandgap of the third junction is smaller than bandgap of the fourth junction. Layer 432 is texturized for enhancing light absorption. Terminals 1-5 in FIGS. 4A-4B are metal electrodes. Electrical connection to the fourth junction is made by a via through which terminal 4 passes. Similarly, electrical connection to the third junction is made by another via through which terminal 3 passes. Similarly, electrical connection to the second junction is made by yet another via through which terminal 2 passes. Layer 400 extends throughout the sidewall of these vias to provide electrical insulation. The vias may be made by a suitable method such as laser or deep RIE (reactive ion etching). Materials of the first, second, and third junctions may be selected from Table 1. Layers 401-404, 410-413, 420-423 and 430-434 are preferably epitaxial layers.

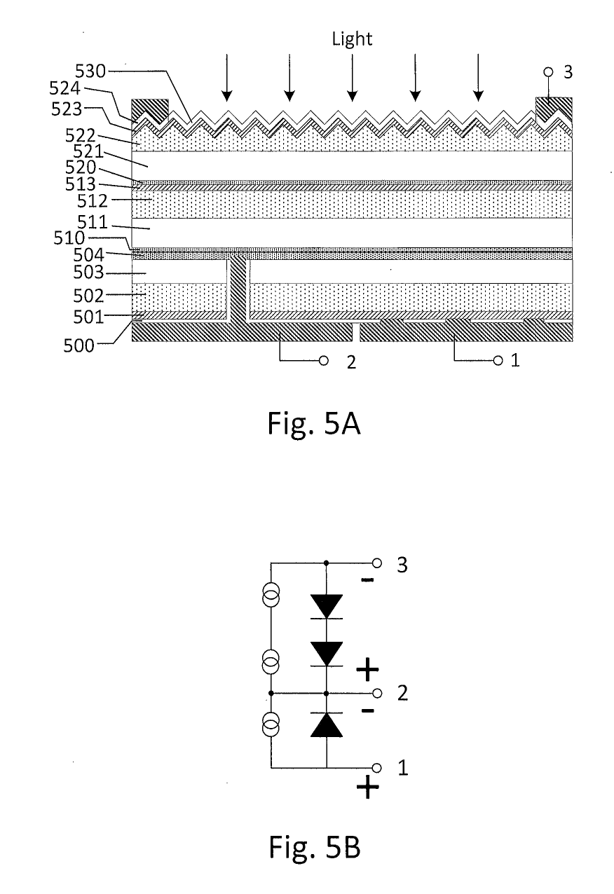

FIG. 5A shows a schematic cross-section of a photovoltaic device, according to an embodiment. FIG. 5B shows an equivalent circuit of the device in FIG. 5A. This device comprises the following layers:
500: a dielectric layer for passivation and insulation of layers 501-504;
501: a p+ doped layer of a first junction;
502: a p doped layer of the first junction
503: an n doped layer of the first junction
504: a buffer layer in case that layer 510 is a III-V compound material; otherwise, layer 504 is an n+ doped layer of the first junction;
510: an n+ doped layer of a second junction;
511: an n doped layer of the second junction;
512: a p doped layer of the second junction;
513/520: p+ and n+ doped layers of a tunnel junction;
521: an n doped layer of a third junction;
522: a p doped layer of the third junction;
523: a p+ doped layer of the third junction;
524: a contact layer;
530: a dielectric layer for passivation and antireflection.

In this embodiment, the first, second and third junctions are depicted planar but can have non-planar shapes. Bandgap of the first junction is smaller than bandgap of the second junction, which is smaller than bandgap of the third junction. Layer 522 is texturized for enhancing light absorption. Terminals 1-3 in FIGS. 5A-5B are metal electrodes. Electrical connection to the second and third junctions is made by a via through which terminal 2 passes. Layer 500 extends throughout the sidewall of the via to provide electrical insulation. The via may be made by a suitable method such as laser or deep RIE (reactive ion etching). Materials of the first, second, and third junctions may be selected from Table 1. This device is identical to the device in the embodiment in FIGS. 3A-3B, except that electrical currents from the second and third junctions are matched (i.e., essentially equal to each other) by adjusting thickness of the layers of the second and third junctions. Layers 501-504, 510-513, and 520-524 are preferably epitaxial layers.

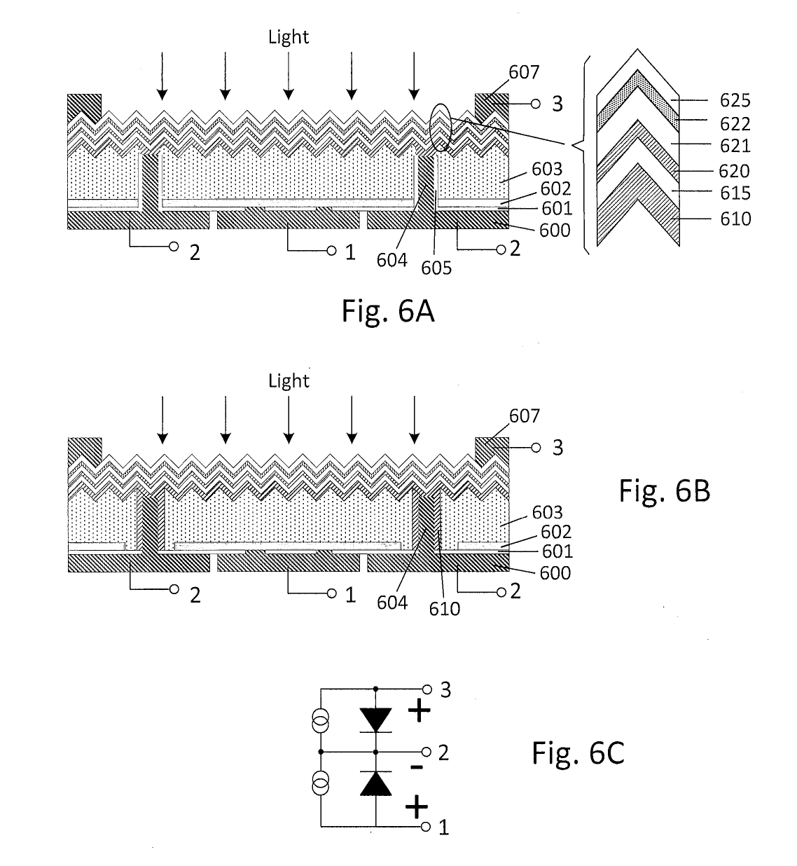

FIG. 6A shows a schematic cross-section of a photovoltaic device, according to an embodiment. FIG. 6B shows a schematic cross-section of a photovoltaic device, according to an embodiment in alternative to that in FIG. 6A. FIG. 6C shows an equivalent circuit of the devices in FIGS. 6A-6B. These devices comprise the following layers:
600: bottom terminals;
601: a dielectric layer for passivation and insulation of layer 602;
602: an n+ doped layer of a first junction;
603: an n doped layer of the first junction;
604: a metal in vias for electrical connection to layer 610;
605 (only in FIG. 6A, not in FIG. 6B): a dielectric layer for insulating side walls through layers 602-603;
607: top terminals;
610: a p+ doped layer of the first junction;
615: a transparent conductive oxide (TCO) layer between the first junction and a second junction;
620: a p+ doped layer of the second junction;
621: an intrinsic layer of the second junction;
622: an n+ doped layer of the second junction;
625: a top TCO layer for antireflection and electrical conduction.

In this embodiment, the first and second junctions may be planar or non-planar. Bandgap of the first junction is smaller than bandgap of the second junction. Layer 603 is texturized for enhancing light absorption. Terminals 1-3 in FIGS. 6A-6B are metal electrodes. Electrical connection to the second junction is made by one or more vias through which terminal 2 passes. As depicted in FIG. 6A, layer 605 extends throughout the sidewall of these vias to provide electrical insulation. Alternatively, as depicted in FIG. 6B, layer 610 extends throughout the sidewall of these vias. The vias may be made by a suitable method such as laser or deep RIE (reactive ion etching). Materials of the first and second junctions may be selected from Table 2.

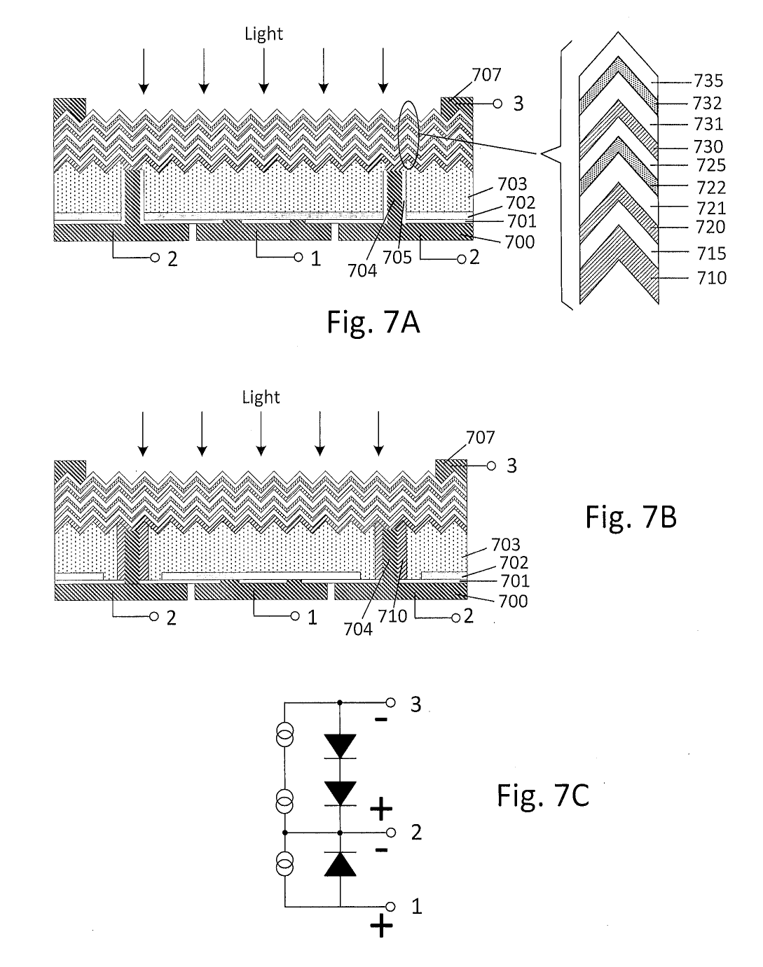

FIG. 7A shows a schematic cross-section of a photovoltaic device, according to an embodiment. FIG. 7B shows a schematic cross-section of a photovoltaic device, according to an embodiment in alternative to that in FIG. 7A. FIG. 7C shows an equivalent circuit of the devices in FIGS. 7A-7B. These devices comprise the following layers:
700: bottom terminals;
701: a dielectric layer for passivation and insulation of layer 702;
702: an n+ doped layer of a first junction;
703: an n doped layer of the first junction;
704: a metal in vias for electrical connection to layer 710;
705 (only in FIG. 7A, not in FIG. 7B): a dielectric layer for insulating side walls through layers 702-703;
707: top terminals;
710: a p+ doped layer of the first junction;
715: a transparent conductive oxide (TCO) layer between the first junction and a second junction;
720: a p+ doped layer of the second junction;
721: an intrinsic layer of the second junction;
722: an n+ doped layer of the second junction;
725: a TCO layer between the second junction and a third junction;
730: a p+ doped layer of the third junction;
731: an intrinsic layer of the third junction;
732: an n+ doped layer of the third junction;
735: a top TCO layer for antireflection and electrical conduction.

In this embodiment, the first and second junctions may be planar or non-planar. Bandgap of the first junction is smaller than bandgap of the second junction. Bandgap of the second junction is smaller than bandgap of the third junction. Layer 703 is texturized for enhancing light absorption. Terminals 1-3 in FIGS. 7A-7B are metal electrodes. Electrical connection to the second and third junctions is made by one or more vias through which terminal 2 passes. As depicted in FIG. 7A, layer 705 extends throughout the sidewall of these vias to provide electrical insulation. Alternatively, as depicted in FIG. 7B, layer 710 extends throughout the sidewall of these vias. Electrical currents from the second and third junctions are matched (i.e., essentially equal to each other) by adjusting thickness of the layers of the second and third junctions. The vias may be made by a suitable method such as laser or deep RIE (reactive ion etching). Materials of the first, second and third junctions may be selected from Table 2.

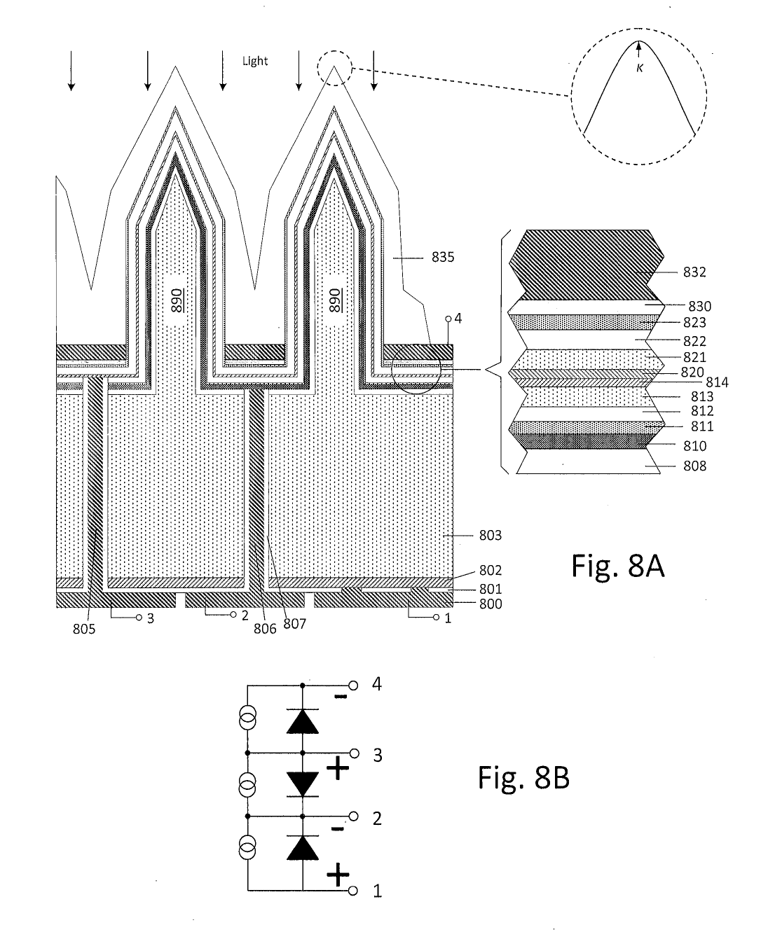

FIG. 8A shows a schematic cross-section of a photovoltaic device, according to an embodiment. FIG. 8B shows an equivalent circuit of the device in FIG. 8A. This device comprises the following layers:
800: bottom terminals;
801: a dielectric layer for passivation and insulation of layer 802;
890: one or more structures essentially perpendicular to the substrate (layer 803 may be part of the substrate);
802: a p+ doped layer of a first junction
803: a p doped layer of the first junction
805: a metal in via for electrical connection to a third junction;
806: a metal in via for electrical connection to a second junction;
807: a dielectric layer for insulating metal 806 and 805;
808: an n doped layer of the first junction;
810: a buffer layer in case that layer 811 is a III-V compound material; otherwise, layer 810 is an n+ doped layer of the first junction;
811: an n+ doped layer of the second junction;
812: an n doped layer of the second junction;
813: a p doped layer of the second junction;
814: a p+ doped layer of the second junction;
820: a p+ doped layer of the third junction;
821: a p doped layer of the third junction;
822: an n doped layer of the third junction;
823: an n+ doped layer of the third junction;
830: a n+ doped contact layer;
832: a conductive layer as top terminal;
835: a cladding layer of a transparent oxide.

In this embodiment, bandgap of the first junction is smaller than bandgap of the second junction, which is smaller than bandgap of the third junction. Layers 808, 810-814, 820-823, 830 and 835 are conformal to the structures 890. Layer 832 is the conductive (e.g., metallic) layer disposed between the structures 890 and is above the first, second and third junctions. Layer 832 may be a material selected from a group consisting of ZnO, Ni, Pt, Al, Au, Ag, Pd, Cr, Cu, Ti, and a combination thereof. Layer 832 is preferably an electrically conductive material such as a metal. Layer 832 preferably has a reflectance (i.e., the fraction of incident electromagnetic power that is reflected) of at least 50% for visible light (i.e., light have a wavelength from 390 to 750 nm) of any wavelength. Layer 832 may have a thickness of at least 5 nm, preferably from about 20 nm to about 200 nm (e.g., about 80 nm). Layer 832 between the structures 890 is preferably connected. Layer 832 may be functional to reflect light incident thereon to the structures so that the light is absorbed by the structures; and/or layer 832 is functional as an electrode of the photovoltaic device.

Curvatures (κ) of the apexes of planar cross-sections through structures 890, layers 808, 810-814, 820, 823 and 830 respectively satisfy the equation

$$κ \geq \frac{n}{λ} ,$$

wherein n is the respective indexes of refraction of structures 890, layers 808, 810-814, 820, 823 and 830 and λ is 380 nm.

Terminals 1-3 in FIGS. 8A-8B are metal electrodes. Electrical connection to the third junction is made by a via through which terminal 3 passes. Similarly, electrical connection to the second junction is made by another via through which terminal 2 passes. Layer 807 extends throughout the sidewall of these vias to provide electrical insulation. The vias may be made by a suitable method such as laser or deep RIE (reactive ion etching). Materials of the first, second, and third junctions may be selected from Table 1. Materials of the first, second, and third junctions may be selected from Table 1. Layers 801-803, 808, 810-814, 820-823, and 830 are preferably epitaxial layers.

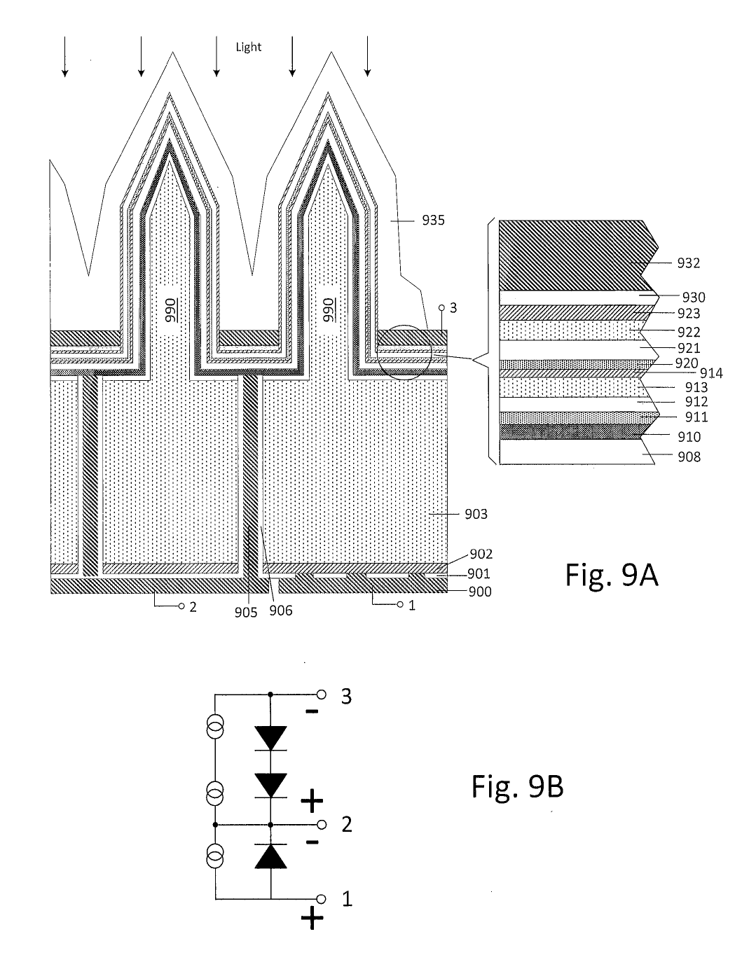

FIG. 9A shows a schematic cross-section of a photovoltaic device, according to an embodiment. FIG. 9B shows an equivalent circuit of the device in FIG. 9A. This device comprises the following layers:
900: bottom terminals;
901: a dielectric layer for passivation and insulation of layer 902;
990: one or more structures essentially perpendicular to the substrate (layer 903 may be part of the substrate);
902: a p+ doped layer of a first junction
903: a p doped layer of the first junction
905: a metal in via for electrical connection to a third junction and a second junction;
907: a dielectric layer for insulating metal 906;
908: an n doped layer of the first junction;
910: a buffer layer in case that layer 911 is a III-V compound material; otherwise, layer 910 is an n+ doped layer of the first junction;
911: an n+ doped layer of the second junction;
912: an n doped layer of the second junction;
913: a p doped layer of the second junction;
914: a p+ doped layer of the second junction;
920: a p+ doped layer of the third junction;
921: a p doped layer of the third junction;
922: an n doped layer of the third junction;
923: an n+ doped layer of the third junction;
930: a n+ doped contact layer;
932: a conductive layer as top terminal;
935: a cladding layer of a transparent oxide.

In this embodiment, bandgap of the first junction is smaller than bandgap of the second junction, which is smaller than bandgap of the third junction. Layers 908, 910-914, 920-923, 930 and 935 are conformal to the structures 990. Layer 932 is the conductive (e.g., metallic) layer disposed between the structures 990 and is above the first, second and third junctions. Layer 932 may be a material selected from a group consisting of ZnO, Ni, Pt, Al, Au, Ag, Pd, Cr, Cu, Ti, and a combination thereof. Layer 932 is preferably an electrically conductive material such as a metal. Layer 932 preferably has a reflectance (i.e., the fraction of incident electromagnetic power that is reflected) of at least 50% for visible light (i.e., light have a wavelength from 390 to 750 nm) of any wavelength. Layer 932 may have a thickness of at least 5 nm, preferably from about 20 nm to about 200 nm (e.g., about 80 nm). Layer 932 between the structures 990 is preferably connected. Layer 932 may be functional to reflect light incident thereon to the structures so that the light is absorbed by the structures; and/or layer 932 is functional as an electrode of the photovoltaic device.

Curvatures (κ) of the apexes of planar cross-sections through structures 990, layers 908, 910-914, 920, 923 and 930 respectively satisfy the equation

$$κ \geq \frac{n}{λ} ,$$

wherein n is the respective indexes of refraction of structures 990, layers 908, 910-914, 920, 923 and 930 and λ is 380 nm.

Terminals 1-3 in FIGS. 9A-9B are metal electrodes. Electrical connection to the second and third junctions is made by a via through which terminal 2 passes. Layer 807 extends throughout the sidewall of the via to provide electrical insulation. The via may be made by a suitable method such as laser or deep RIE (reactive ion etching). Materials of the first, second, and third junctions may be selected from Table 1. Layers 901-903, 908, 910-914, 920-923, and 930 are preferably epitaxial layers.

Electrical currents from the second and third junctions are matched (i.e., essentially equal to each other) by adjusting thickness of the layers of the second and third junctions.

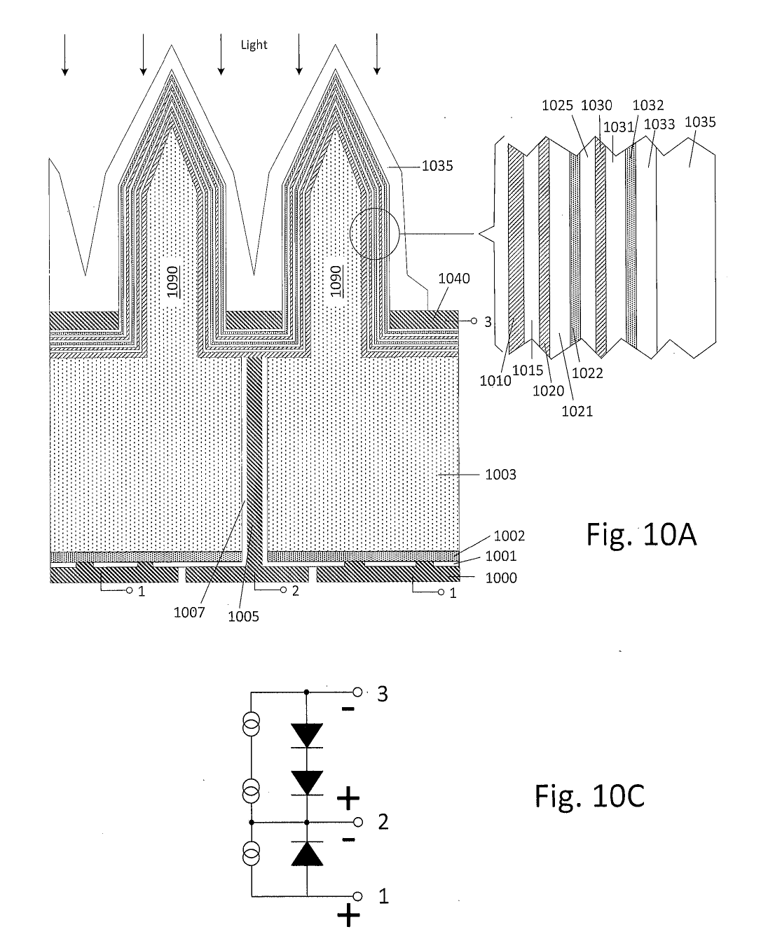

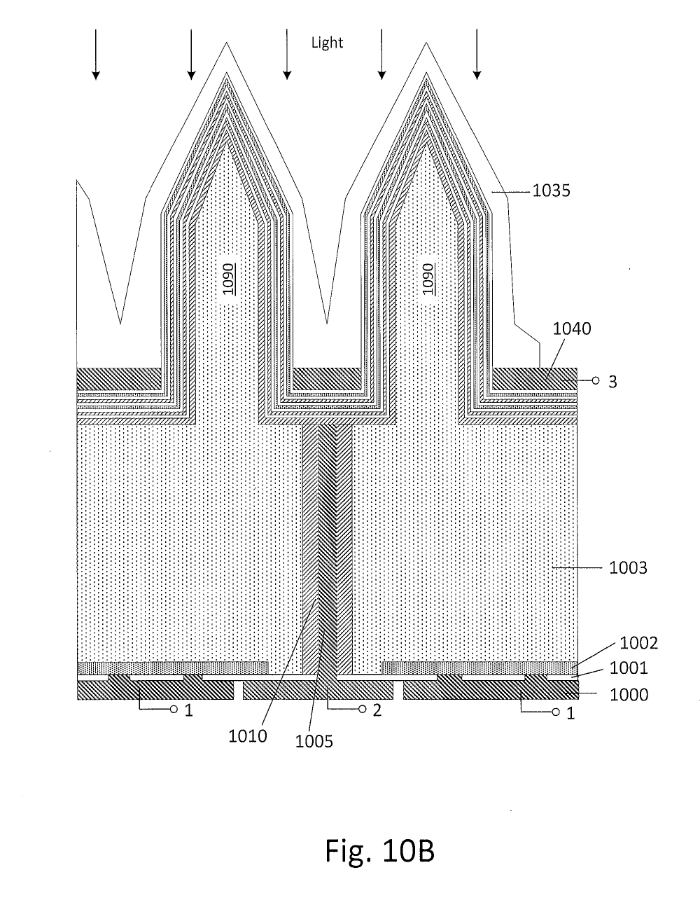

FIG. 10A shows a schematic cross-section of a photovoltaic device, according to an embodiment. FIG. 106 shows a schematic cross-section of a photovoltaic device, according to an embodiment in alternative to that in FIG. 10A. FIG. 10C shows an equivalent circuit of the device in FIGS. 10A-10B. These devices comprise the following layers:
1000: bottom terminals;
1001: a dielectric layer for passivation and insulation of layer 1002;
1090: one or more structures essentially perpendicular to the substrate (layer 1003 may be part of the substrate);
1002: a n+ doped layer of a first junction;
1003: a n doped layer of the first junction;
1005: a metal in via for electrical connection to the first junction, a third junction and a second junction;
1007: a dielectric layer for insulating metal 1005;
1010: a p+ doped layer of the first junction;
1015: a TCO layer between the first junction and the second junction;
1020: a p+ doped layer of the second junction;
1021: an intrinsic layer of the second junction;
1022: an n+ doped layer of the second junction;
1025: TCO layer between the second junction and the third junction;
1030: a p+ doped layer of the third junction;
1031: an intrinsic layer of the third junction;
1032: an n+ doped layer of the third junction;
1033: a top TCO layer for antireflection and electrical conduction;
1035: a cladding layer mad of a transparent oxide;
1040: a conductive layer as top terminal.

In this embodiment, bandgap of the first junction is smaller than bandgap of the second junction, which is smaller than bandgap of the third junction. Layers 1010, 1015, 1020-1022, 1025, 1030-1033, and 1035 are conformal to the structures 1090. Layer 1040 is the conductive (e.g., metallic) layer disposed between the structures 1090 and is above the first, second and third junctions. Layer 1040 may be a material selected from a group consisting of ZnO, Ni, Pt, Al, Au, Ag, Pd, Cr, Cu, Ti, and a combination thereof. Layer 1040 is preferably an electrically conductive material such as a metal. Layer 1040 preferably has a reflectance (i.e., the fraction of incident electromagnetic power that is reflected) of at least 50% for visible light (i.e., light have a wavelength from 390 to 750 nm) of any wavelength. Layer 1040 may have a thickness of at least 5 nm, preferably from about 20 nm to about 200 nm (e.g., about 80 nm). Layer 1040 between the structures 1090 is preferably connected. Layer 1040 may be functional to reflect light incident thereon to the structures so that the light is absorbed by the structures; and/or layer 1040 is functional as an electrode of the photovoltaic device.

Curvatures (κ) of the apexes of planar cross-sections through structures 1090, layers 1010, 1015, 1020-1022, 1025, 1030-1033, and 1035 respectively satisfy the equation

$$κ \geq \frac{n}{λ} ,$$

wherein n is the respective indexes of refraction of structures 1090, layers 1010, 1015, 1020-1022, 1025, 1030-1033, and 1035 and λ is 380 nm.

Terminals 1-3 in FIGS. 10A-10B are metal electrodes. Electrical connection to the second and third junctions is made by a via through which terminal 2 passes. Layer 1007 extends throughout the sidewall of the via to provide electrical insulation. Alternatively, as depicted in FIG. 10B, layer 1010 extends throughout the sidewall of the via. The via may be made by a suitable method such as laser or deep RIE (reactive ion etching). Materials of the first, second, and third junctions may be selected from Table 2.

Electrical currents from the second and third junctions are matched (i.e., essentially equal to each other) by adjusting thickness of the layers of the second and third junctions.

The TCO layers 1015, 1025 and 1035 may have non-uniform thickness to reduce optical loss. For example, portions of the TCO layers 1015, 1025 and 1035 directly under the conductive layer 1040 may have a greater thickness than other portions of the TCO layers 1015, 1025 and 1035.

A method of converting light to electricity comprises: exposing the photovoltaic device to light; absorbing the light and converting the light to electricity using the photovoltaic device; drawing an electrical current from the photovoltaic device.

A photo detector according to an embodiment comprises the photovoltaic device, wherein the photo detector is configured to output an electrical signal when exposed to light.

A method of detecting light comprises: exposing the photovoltaic device to light; measuring an electrical signal from the photovoltaic device. The electrical signal can be an electrical current, an electrical voltage, an electrical conductance and/or an electrical resistance.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A photovoltaic device operable to convert light to electricity, comprising a substrate, a first junction, a second junction and a third junction; wherein the first junction and the second junction are arranged with opposite polarity and the second junction and the third junction are arranged with opposite polarity.

2. The photovoltaic device of claim 1, further comprising a first terminal directly electrically connected to anodes of the first and second junctions or to cathodes of the first and second junctions.

3. The photovoltaic device of claim 1, further comprising a second terminal directly electrically connected to anodes of the second and third junctions or to cathodes of the second and third junctions.

4. The photovoltaic device of claim 1, further comprising a second via configured to accommodate direct electrical connection to the second junction.

5. The photovoltaic device of claim 4, wherein sidewall of the second via is covered by an electrically insulating material.

6. The photovoltaic device of claim 4, wherein sidewall of the second via is covered by a material of the first junction.

7. The photovoltaic device of claim 1, wherein the second and third junctions are configured such that electrical currents of the second and third junctions are essentially equal.

8. The photovoltaic device of claim 1, further comprising one or more structures essentially perpendicular to the substrate, wherein the first, second and third junctions are conformally disposed on the one or more structures.

9. The photovoltaic device of claim 8, wherein at least some of the one or more structures each have a tapered portion and an untapered portion.

10. The photovoltaic device of claim 9, wherein the tapered portion has a height of about 10% to 100% of a height of the structures.

11. The photovoltaic device of claim 9, wherein sidewall of the tapered portion and the substrate form an angle from 60 to 85 degrees.

12. The photovoltaic device of claim 9, wherein the tapered portion is a cone or frustum.

13. The photovoltaic device of claim 9, wherein the tapered portion does not have a planar surface at an apex thereof.

14. The photovoltaic device of claim 9, wherein curvature (κ) of an apex of a planar cross-section through the tapered portion satisfies an equation
$$\geq \frac{n}{λ} ,$$
wherein n is the index of refraction of the taper, portion and λ is 380 nm.

15. The photovoltaic device of claim 9, wherein the first, second and third junctions are covered by a cladding layer.

16. The photovoltaic device of claim 15, wherein a refractive index of the cladding layer is smaller than refractive indexes of the first, second and third junctions.

17. The photovoltaic device of claim 8, further comprising one or more transparent conductive oxide layers conformally disposed on the structures and the substrate.

18. The photovoltaic device of claim 17, wherein thickness of a portion of the one or more transparent conductive oxide layers that is on the structures is smaller than thickness of another portion of the one or more transparent conductive oxide layers on the substrate.

19. A method of making a photovoltaic device with one or more structures wherein the one or more structures comprise a tapered portion; the method comprising:
making the one or more structures by reactive ion etching the substrate with a metal layer as a mask;
forming the tapered portion by etching the one or more structures.

20. The method of claim 19, further comprising:
making a polymer mold by pouring precursors of the polymer onto the substrate following by curing;
removing the polymer mold and coating the polymer mold with a layer of oxide;
stamping an uncured ceramic material with the polymer mold;
forming a ceramic structure by curing the uncured ceramic material.
